(19) United States
(12) Patent Application Publication
(10) Pub. No.: US 2002/0018338 A1
(43) Pub. Date: Feb. 14, 2002

(54) Insert molded heat sink assembly

(76) Inventor: Kevin A. McCullough, Warwick, RI (US)

Correspondence Address: BARLOW, JOSEPHS & HOLMES, LTD., 101 DYER STREET, 5TH FLOOR, PROVIDENCE, RI, 02903, US

(21) Appl. No.: 09/757,465

(22) Filed: Jan. 10, 2001

Related U.S. Application Data
(60) Provisional application No. 60/175,494, filed on Jan. 11, 2000.

(51) Int. Cl. H05K 7/20

(52) U.S. Cl. 361/709

(57) ABSTRACT

An insert molded heat sink assembly for dissipating heat from a heat generating source includes a polymer base that contacts the heat generating source with a heat dissipating element array embedded therein. A pin grid array, fins or other structures are embedded directly into the polymer base using a molding process. In accordance with the present invention the heat dissipating elements are insert molded around to produce a completed heat sink. Moreover, the polymer base is preferably a highly thermally conductive polymer composition. Also, the geometry of the heat dissipating members, such as a pin or fin array, is optimized to improve the overall performance of the heat sink assembly.

### BACKGROUND OF THE INVENTION

The present invention relates generally to the cooling of electronic solid state and integrated circuit devices. More specifically, the present invention relates to the manufacture of heat sink assemblies to dissipate heat away from a heat-generating object, such as an electronic component.

In the electronics and computer industries, it has been well known to employ various types of electronic device packages and integrated circuit chips, such as the PENT-UP central processing unit chip (CPU) manufactured by Intel Corporation and RAM (random access memory) chips. These integrated circuit chips have a pin grid array (PA) package and are typically installed into a socket, which is soldered to a computer circuit board. These integrated circuit devices, particularly the CPU microprocessor chips, generate a great deal of heat during operation which must be removed to prevent adverse effects on operation of the system into which the device is installed. For example, a PENTIUM microprocessor, containing millions of transistors, is highly susceptible to overheating which could destroy the microprocessor device itself or other components proximal to the microprocessor.

In addition to the PENTIUM microprocessor discussed above, there are many other types of semiconductor device packages that are commonly used in computer equipment, for example. Recently, various types of surface mount packages, such as BGA (ball grid array) and LGA (land grid array) type semiconductor packages have become increasingly popular as the semiconductor package of choice for computers.

Also, microprocessors are commonly being installed onto a circuit board that is, in turn, installed into a motherboard or other similar primary circuit board. For example, microprocessors, such as the Pentium II and the Celeron from Intel, are “processor cards” which are installed into a motherboard of a computer in similar fashion to the way a modem is installed into a motherboard. On a given processor card is typically the processor semiconductor device package itself along with any other chips or semiconductor devices that are necessary for the operation of the card, such cache chips, or the like. The processor package may be installed into the processor card via a pin grid, ball grid, land grid array and with a socket such as a ZIF or ball grid socket.

In similar fashion to the earlier semiconductor devices discussed above, the processor cards like the Pentium II and Celeron also suffer from excessive generation of heat. In particular, the processor semiconductor device package on the card generates the heat that is of most concern. A given surface of the component will, as a result, be very hot. If such heat is not properly dissipated, the processor semiconductor device package and the entire processor card or component will eventually fail.

In view of the foregoing, efforts have been made to supply a heat-dissipating member, such as a heat sink, into thermal communication with a semiconductor device package. These efforts typically include the employment of a block heat sink member, such as an extruded aluminum member with upstanding pins, along with a separate steel spring clip to maintain the heat sink in thermal communication with the semiconductor device package. Prior art attempts also include separate clips that embrace the semiconductor package with a heat sink member that either snaps or threads into the clips to complete the assembly.

The foregoing heat sink assemblies of the prior art suffer from the disadvantages of having multiple components and the high cost associated therewith. These multiple component heat sink assemblies typically include expensive machined or extruded heat conductive metal, such as aluminum. Other parts, such as springs or addition clips require separate machining steps and/or molds for production.

In view of the foregoing, there is a demand for a heat sink assembly that attaches to a heat generating semiconductor device package. There is a demand for a heat sink assembly can be easily formed into a single member with no separate parts. In addition, there is a demand for complete heat sink assembly to be completely molded into its finished shape without requiring additional assembly or machining steps.

### SUMMARY OF THE INVENTION

The present invention preserves the advantages of prior art heat sink assemblies for integrated circuit devices, such as microprocessors. In addition, it provides new advantages not found in currently available assemblies and overcomes many disadvantages of such currently available assemblies.

The invention is generally directed to the novel and unique heat sink assembly with particular application in cooling microprocessor integrated circuit devices, such as semiconductor device package. The heat sink assembly of the present invention enables the simple, easy and inexpensive assembly, use and maintenance of a heat sink assembly while realizing superior heat dissipation.

The molded heat sink assembly includes an integrally molded base and may include an attachment clip device. The assembly removes heat from a heat generating semiconductor device package through a conductive surface of the device. The heat sink assembly also includes a heat conductive base member having a substantially flat bottom surface adapted to be positioned in flush thermal communication with a heat generating semiconductor device package. A number of heat dissipating elements such as an array of pin or fins are molded into and extend upwardly from the thermally conductive base member. In many cases the pins or fins are metallic and formed from copper or aluminum however other materials may also be used in their fabrication. The pin or fin array is insert molded into the base to produce an integral one-piece heat sink.

In operation, the integral heat sink arrangement is positioned over the semiconductor device package to be cooled with the base portion being in thermal communication with the upper surface of the heat-generating device. The heat sink can be attached to the semiconductor device using any manner of attachment commonly known in the art. For example, thermally conductive adhesive, spring clips or fasteners can be used to attach the heat sink to the heat-generating device. The primary objective in attachment is to maintain flush thermal communication between the heat sink and the device.

It is therefore an object of the present invention to provide a complete heat sink assembly that can accommodate a wide array of types of semiconductor device packages.

It is an object of the present invention to provide a complete heat sink assembly that includes heat-conducting members and an injection molded base structure with high aspect ratio thermally conductive filler therein.

Another object of the present invention is to provide a composite heat sink assembly that includes highly thermally conductive heat dissipating members and a base manufactured of a thermally conductive moldable polymer.

It is yet a further object of the present invention to provide a heat sink that can attach to and passively cool a heat-generating surface.

### BRIEF DESCRIPTION OF THE DRAWINGS

The novel features which are characteristic of the present invention are set forth in the appended claims. However, the invention's preferred embodiments, together with further objects and attendant advantages, will be best understood by reference to the following detailed description taken in connection with the accompanying drawings in which:

FIG. 1 is a perspective view of the heat sink assembly of the present invention;

FIG. 2 is a top view of the heat sink assembly of the present invention of FIG. 1;

FIG. 3 is a cross-sectional view through the line 3-3 of FIG. 2;

FIG. 4 is a cross-sectional view of the heat sink assembly of the present invention installed on a semiconductor device package; and

FIG. 5 is a perspective view of an alternative embodiment of the present invention.

### DETAILED DESCRIPTION OF THE PREFERRED EMBODIMENT

The present invention provides a heat sink assembly 10 for attachment to a wide range of types of semiconductor device packages. These packages may be attached to a circuit board such as a motherboard or daughter card.

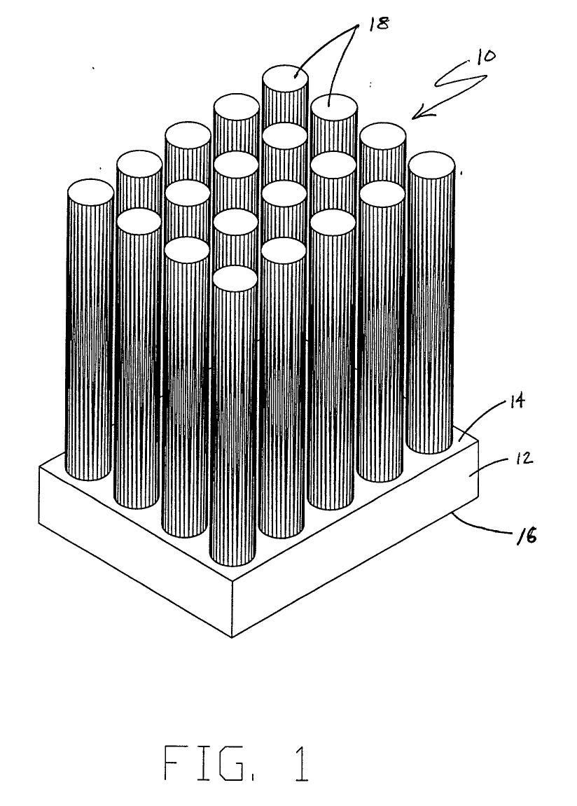

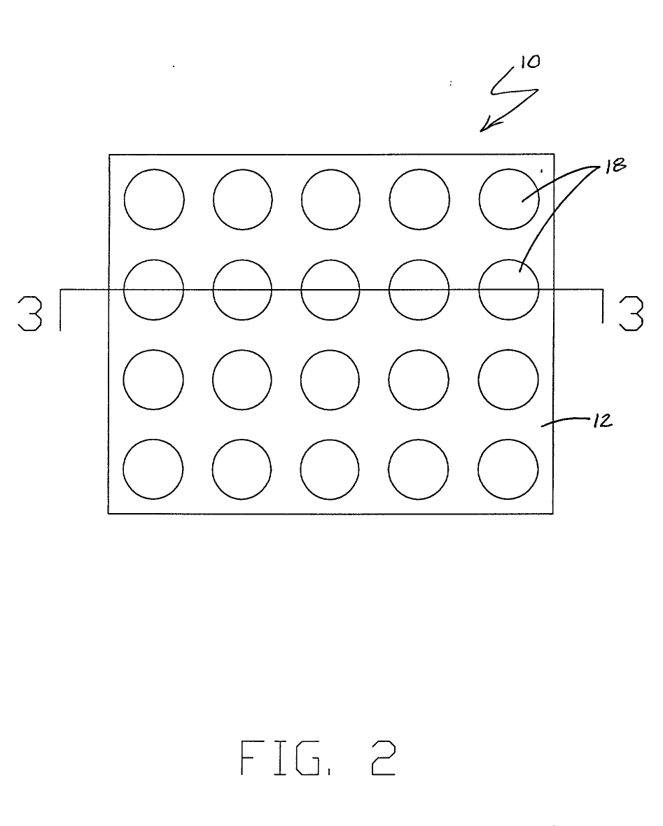

Referring first to FIG. 1, a perspective view of the preferred embodiment of the integrally molded heat sink assembly 10 of the present invention is shown. This heat sink assembly 10 includes a base member 12 having a top surface 14 and bottom surface 16. Emanating upwardly from the top surface are a number of pin structures 18 serving as heat dissipating members for dissipating heat into the ambient air. FIG. 2 illustrates a top view of the heat sink assembly 10 of the present invention where pins are molded into the actual base member 12.

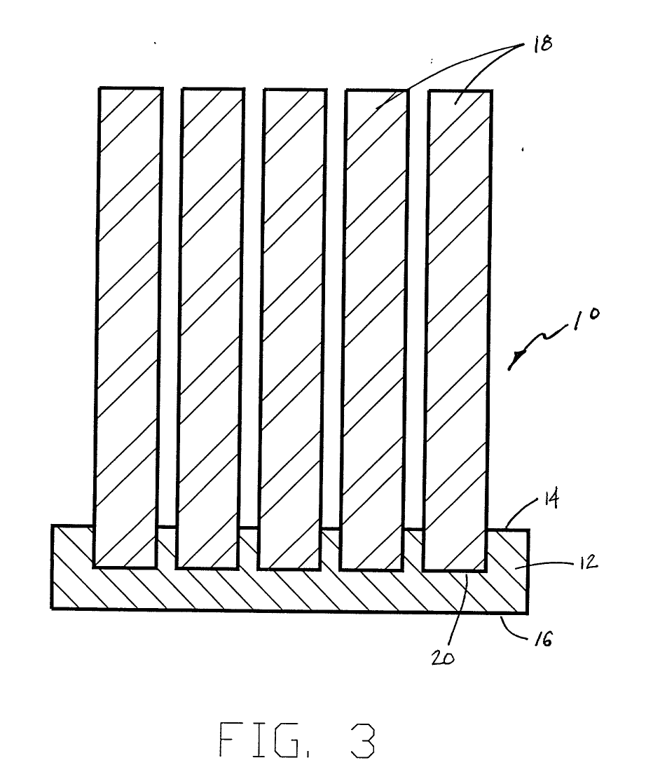

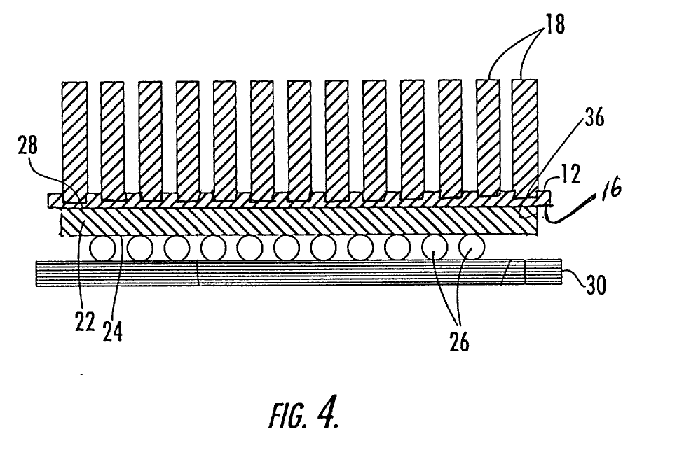

Turning now to FIGS. 3 and 4, details of the construction of the heat sink assembly 10 of the present invention are shown. FIG. 3 is illustrates a general cross-sectional view through the line 3-3 of FIG. 2 of the heat sink assembly 10 of the present invention. The base member 12 of the heat sink assembly 10 includes a bottom surface 16 that is designed to be mounted in thermal communication with the top surface 28 of a semiconductor device 22. During fabrication, the heat dissipating members 18 are imbedded into the base member 12 and are preferably elongated to maximize surface area to enhance heat dissipation. This is accomplished by inserting the array of pin members 18 into the inner surface of an injection mold cavity and injection molding the base member 12 around the bottom ends 20 of the heat dissipating members 18. This process is known in the art as insert molding. In the preferred embodiment, the pin members are made from aluminum although the pin members can be any thermally conductive material such as copper or magnesium. The base member 12 is molded from a thermally conductive polymer composition such as a liquid crystal polymer filled with carbon fiber.

Still referring to FIG. 4 the heat sink 10 of the present invention is mounted on a semiconductor package 22 that includes a bottom surface 24 with a number of electrical interconnections thereon, such as solder balls 26 as shown. Alternatively, semiconductor device package 22 may be of a pin grid array configuration where an array of pins (not shown) is employed instead of the ball array 26. As stated above, the semiconductor package 22 tends to run at high temperatures. More specifically, it is the top surface 28 that is particularly hot and needs heat dissipation. FIG. 4 illustrates the installation and attachment of the heat sink assembly 10 of the present invention to the semiconductor device package 22 installed on a circuit board 30. In this arrangement, the lower surface 16 of the base member 12 is in thermal communication with the top surface 28 of the heat-generating semiconductor 22 and the heat dissipating members 18 emanate upwardly into the air for optimum heat exchange from the base member 12.

Referring now to both FIGS. 3 and 4, the installation of the preferred embodiment of the present invention is shown. The integral heat sink assembly 10, with heat dissipating base 12 and pin members 18 is, as one unit, attached the semiconductor device package 22 to be cooled. This attachment can be accomplished by several methods well known in the art. In this example, a thermally conductive adhesive is applied to the bottom surface 16 of the heat sink 10 prior to applying it to the top surface 28 of the heat generating semiconductor 22, resulting in uniform contact and thermal conductivity between the hot surface 28 and the heat dissipating surface 16.

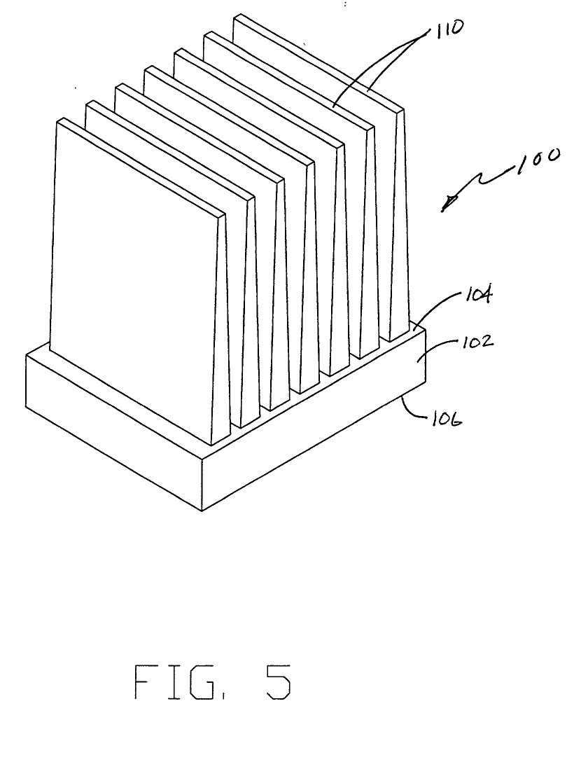

Turning now to FIG. 5, a perspective view of an alternative embodiment of the heat sink assembly 100 of the present invention is shown. In particular, the heat sink assembly 100 includes a base member 102 with a top surface 104 and bottom surface 106. Emanating upwardly from the top surface 104 of the base member 102 are a number of heat dissipating elements 110 which are shown, in this embodiment, as fin elements. In this alternative embodiment, heat sink 100 fin shaped heat-dissipating members 110 are substituted for pin shaped heat-dissipating members 18. The specific geometry of fins versus pins is determined by the application at hand, including the anticipated airflow, amount of heat to be dissipated and amount of surface area required to dissipate the heat.

The manufacture of the heat sink 100 of this embodiment is the same as described above. The fin members 110 are installed in the surface of the injection mold cavity and the base member 102 is injection molded around them using a thermally conductive polymer composition. Similarly, the fin material in the preferred embodiment is aluminum, however, any thermally conductive material can be employed and such changes are anticipated under this disclosure.

The present invention has a wide range of applications and can be easily adapted for such applications. Further applications include any circuit board configuration where a heat generating device is provided on a circuit board or similar substrate and where a receiving structure. The present invention may be easily adapted to an application where the circuit board containing the heat-generating device is encased in a housing, such as a Pentium II configuration. In this arrangement (not shown), both the preferred embodiment and the alternative embodiments my be modified to accommodate such a package.

It is preferred that the present invention be manufactured using metallic pins or fins with an overmolded base member 12 from a unitary molded member of a thermally conductive polymer or the like. For example, a polymer base matrix loaded with conductive filler material, such as carbon fiber, may be employed as the material for the present invention. Such unitary construction is unlike that found in the prior and provides significant advantages including low cost, ease of manufacture and flexibility of heat geometry due to the ability to mold the assembly as opposed to machining it. Fins and a pin grid configuration are shown but various other heat sink fin configurations, such as a radial fin array, may be employed and still be within the scope of the present invention.

It would be appreciated by those skilled in the art that various changes and modifications can be made to the illustrated embodiments without departing from the spirit of the present invention. All such modifications and changes are intended to be covered by the appended claims.

What is claimed is:

1. An insert molded heat sink assembly for removing heat from a semiconductor device package, comprising:
a base member of thermally conductive moldable polymer material; said base member having a bottom surface and a top surface; and
a plurality of heat dissipating elements emanating upwardly from said top surface of said base member; said heat dissipating elements being of a second conductive material from said base member;
whereby said bottom surface of said base member is in thermal communication with said semiconductor device package.

2. The heat sink assembly of claim 1, wherein said heat dissipating members are aluminum.

3. The heat sink assembly of claim 1, wherein said heat dissipating members are magnesium.

4. The heat sink assembly of claim 1, wherein said heat dissipating members are copper.

5. The heat sink assembly of claim 1, wherein said heat dissipating members are fin shaped.

6. The heat sink assembly of claim 1, wherein said heat dissipating members are rod shaped.

7. A method of manufacturing a heat sink assembly for removing heat from a semiconductor device package, comprising the steps of:
providing a plurality of heat dissipating members having a main body portion with a first end and a second end opposing said first end;
molding a base member of thermally conductive moldable polymer material; said base member having a bottom surface and a top surface; and
insert molding said heat dissipating members within said base member with said first ends of said heat dissipating members embedded within said base member and said second ends emanating above said top surface of said base member.

8. The method of claim 7, wherein said step of providing heat-dissipating members is providing aluminum members.

9. The method of claim 7, wherein said step of providing heat-dissipating members is providing magnesium members.

10. The method of claim 7, wherein said step of providing heat-dissipating members is providing copper members.

11. The method of claim 7, wherein said step of providing heat-dissipating members is providing fin shaped members.

12. The method of claim 7, wherein said step of providing heat-dissipating members is providing rod shaped members.
